(19) United States
(12) Patent Application Publication
(10) Pub. No.: US 2007/0045833 A1
(43) Pub. Date: Mar. 1, 2007

(54) Copper bump barrier cap to reduce electrical resistance

(76) Inventors: Ting Zhong, Tigard, OR (US); Shriram Ramanathan, Portland, OR (US); Gerald S. Leatherman, Hillsboro, OR (US); Baohua Niu, Portland, OR (US); Ebrahim Andideh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/212,999

(22) Filed: Aug. 25, 2005

(51) Int. Cl. H01L 23/48; H01L 23/52; H01L 29/40

(52) U.S. Cl. 257/734

(57) ABSTRACT

A controlled collapse chip connection (C4) comprises a copper metal C4 bump formed on an integrated circuit substrate, where the C4 bump includes a metal barrier cap to prevent electromigration of the copper metal. The barrier cap is formed from nickel or cobalt and it can either be formed on a top surface of the C4 bump or it can encapsulate the C4 bump. A method of forming the C4 bump with the barrier cap comprises providing an integrated circuit substrate, depositing a photoresist layer on a top surface of the integrated circuit substrate, exposing and developing the photoresist layer to form an opening, depositing copper metal into the opening to form a C4 bump, plating a metal barrier layer onto a surface of the C4 bump, and stripping the photoresist layer.

### BACKGROUND

The controlled collapse chip connection (C4), also known as the “flip-chip”connection, is a configuration by which a semiconductor chip can be coupled to a carrier, for example, a computer motherboard. A C4 configuration uses an array of solder bumps or balls that are arranged around the surface of the semiconductor chip, either in an area array or a peripheral configuration. The semiconductor chip is placed face down on the carrier. When heat is applied, the solder bumps reflow to the integrated circuit pads (IC pads) joining the semiconductor chip to the carrier. A C4 configuration provides high input/output density, uniform chip power distribution, improved cooling capability, and high reliability. C4 technology has also increased packaging density, data bandwidths, and operating frequencies while reducing system-level noise.

In some C4 structures, each solder ball is formed atop a copper pad that is directly coupled to one or more interconnect layers within the integrated circuit. The solder balls may be formed of tin (Sn) or a tin-lead (Sn—Pb) alloy. In other C4 structures, the solder balls may be formed using copper metal or a copper alloy and the copper solder balls may then be coupled to Sn or Sn—Pb solder balls formed on the carrier (e.g., the motherboard) rather than on the integrated circuit itself. In these configurations, a problem that often arises with C4 structures is device failure around the copper-tin interface or the copper-tin alloy interface due to electromigration that leaves voids in the structure and forms intermetallic compounds (i.e., Cu—Sn compounds).

FIG. 1 is a scanning electron microscope (SEM) photograph of a C4 structure 100 that shows the interface 102 between a copper pad 104 and a tin solder bump 106. Electromigration has caused copper metal from the copper pad 104 to penetrate into the tin solder bump 106, as shown by copper areas 108 that are outlined with dashes. The electromigration of copper leaves behind voids 110 at the copper-tin interface 102. The voids 110 degrade the current carrying capacity of the C4 structure 100, leading to an increase in the electrical resistance of the C4 structure 100 and a reduction in device reliability and performance.

### BRIEF DESCRIPTION OF THE DRAWINGS

FIG. 1 is a SEM photograph of a C4 structure.

FIG. 2 illustrates a conventional C4 connection.

FIG. 3A illustrates a C4 connection in accordance with an implementation of the invention.

FIG. 3B illustrates a C4 connection in accordance with another implementation of the invention.

FIG. 4 is a method of forming a barrier cap on a C4 connection in accordance with an implementation of the invention.

FIG. 5A to 5C are SEM photographs of a C4 connection being formed in accordance with an implementation of the invention.

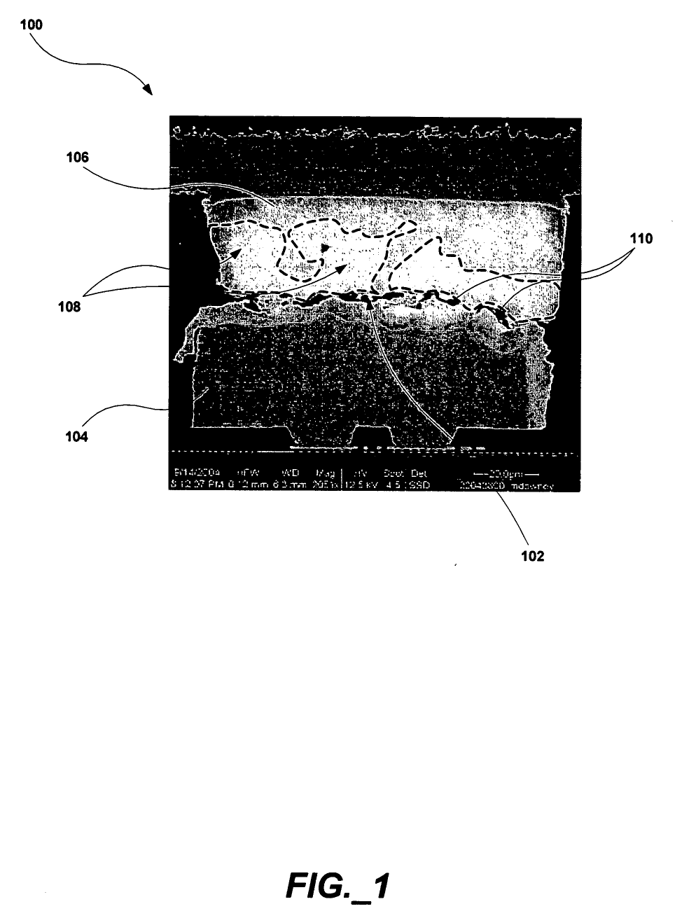

### DETAILED DESCRIPTION

Described herein are systems and methods of reducing the electrical resistance of C4 structures. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention include a copper structure used in a C4 connection, where the copper structure has a barrier cap on a surface of the copper structure that normally interfaces with a tin solder or a tin alloy solder. In one implementation, the barrier cap may be formed from nickel metal. In another implementation, the barrier cap may be formed from cobalt metal.

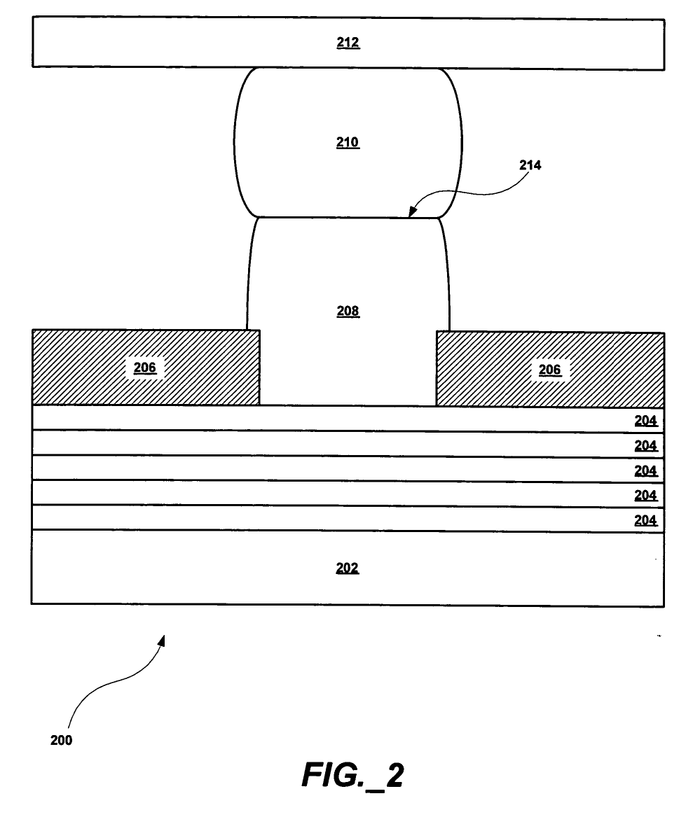

FIG. 2 illustrates an conventional C4 connection. An integrated circuit 200 is shown that includes a semiconductor substrate 202. Formed on or within the semiconductor substrate 202 are devices such as transistors and capacitors (not shown). On a top surface of the semiconductor substrate 202 are formed multiple interconnect layers 204 that serve to interconnect the various devices on the semiconductor substrate 202. The interconnect layers 204 may include metallization layers consisting of metal interconnects separated by dielectric material. The interconnect layers 204 may also include inter-level dielectric (ILD) layers used to separate and insulate the metallization layers from one another. Vias may penetrate through the ILD layers to connect the metallization layers together.

A passivation layer 206 is generally formed atop the final interconnect layer 204. The passivation layer 206 seals and protects the integrated circuit and interconnect layers 204 from damage and contamination. The passivation layer 206 may be formed from many different materials, including but not limited to polyimide. The passivation layer 206 may be formed using well known processes in the art that include, but are not limited to, physical vapor deposition (PVD), chemical vapor deposition (CVD), plasma enhanced chemical vapor deposition (PECVD), spin-on processes, etc.

Openings may be etched in the passivation layer 206 allowing electrical elements from the environment outside of the integrated circuit 200 to access the interconnect layers 204, for instance, electrical probes and/or wire bonds that are part of a carrier (e.g., a motherboard) upon which the integrated circuit 200 is mounted.

A copper bump 208 may be mounted within the opening in the passivation layer. The copper bump 208 provides the final electrical connection between the interconnect layers 204 and the environment outside of the integrated circuit 200. The copper bump 208 is generally formed using either copper metal or a copper alloy. The copper bump 208 may be formed using well known processes in the art that include, but are not limited to, CVD, PVD, atomic layer deposition (ALD), PECVD, electroplating, and electroless plating.

The copper bumps 208 generally fill several important functions. For example, copper bumps 208 provide a standoff that can produce a controlled gap between the integrated circuit 200 and a carrier substrate. If the interconnect length is close to zero, any thermal expansion mismatch will cause extreme stress concentrations. The copper bumps 208 act as a short lead to relieve these stresses. Another important function is the copper bumps 208 help reduce openings and improve the yield of a C4 process.

The copper bump 208 is generally aligned with a solder bump 210 formed on a carrier substrate 212, such as a computer motherboard. The solder bump 210 is generally formed using tin or a tin alloy, such as a tin-silver alloy or a tin-lead alloy. The copper bump 208 and the tin solder bump 210 on the carrier 212 are made to contact one another, as shown, and are then reflowed to form a permanent electrical coupling between the integrated circuit and the carrier.

As described above, the electromigration tendencies of copper tend to cause issues at a copper-tin interface 214 (i.e., where the copper C4 bump 208 is reflowed and coupled to the tin solder bump 210). These issues include the formation of voids and intermetallic compounds that increase the electrical resistance of the C4 connection and decrease the reliability of the C4 connection, thereby reducing the overall performance of the connection.

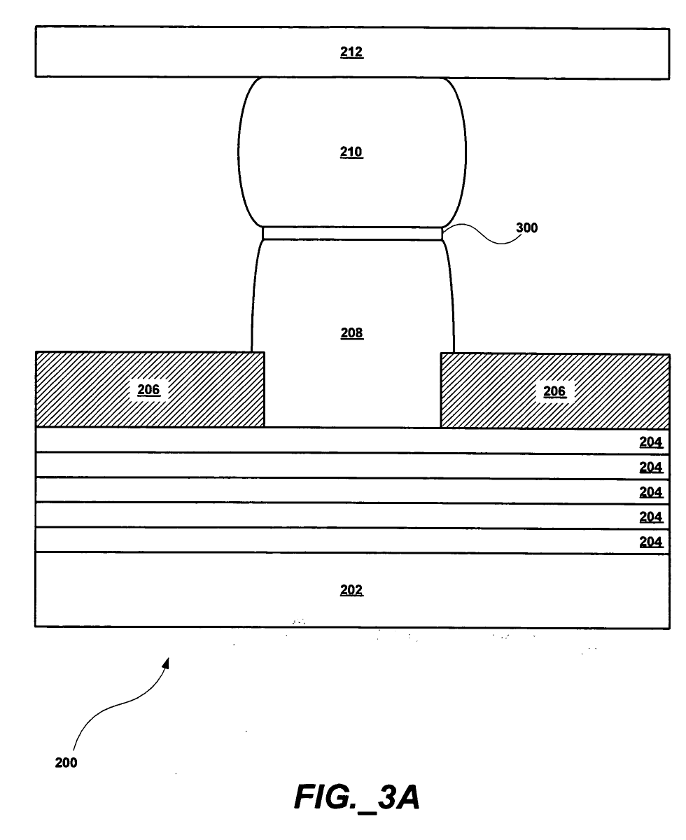

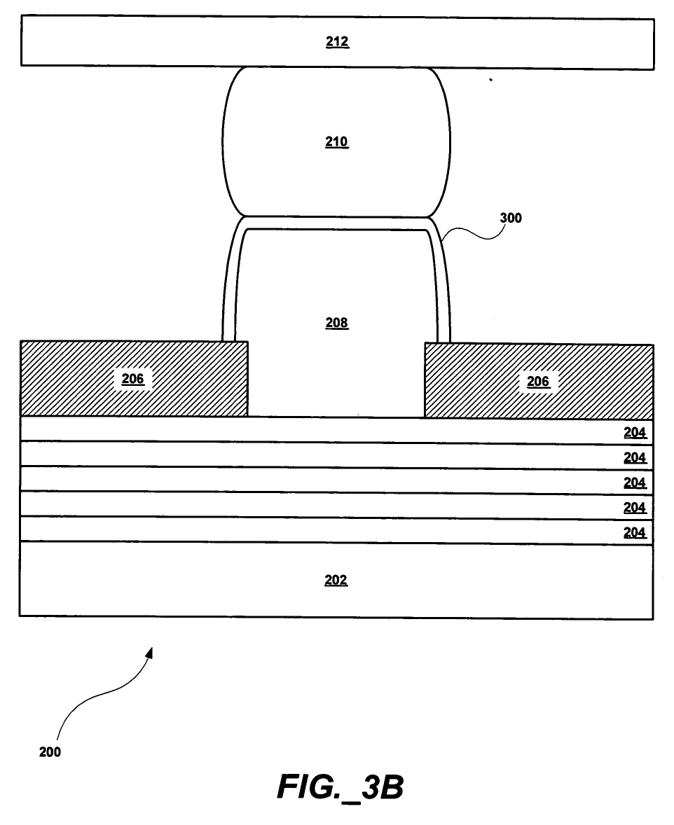

FIG. 3A illustrates a C4 connection that is built in accordance with an implementation of the invention that addresses the aforementioned problems. The implementation shown in FIG. 3 includes a barrier cap 300 formed on a top surface of the copper bump 208. In various implementations, the barrier cap 300 may be formed using nickel metal or cobalt metal. In other implementations, metals other than nickel or cobalt may be used. Accordingly, when the copper bump 208 of the integrated circuit 200 is coupled to a tin solder bump 210 of a carrier 212, the barrier cap 300 may substantially reduce or entirely prevent the electromigration of copper metal into the tin or tin alloy metal, thereby substantially reducing or eliminating the formation of voids and intermetallic compounds at the copper-tin interface. Again, reducing the formation of voids and intermetallic compounds improves the current carrying capacity of the C4 connection and enables the maximum current carried by the C4 connection to be increased for next generation products.

FIG. 3B illustrates an alternate barrier cap 300 for a C4 connection, in accordance with another implementation of the invention. As shown, the barrier cap 300 of FIG. 3B encapsulates the entire copper C4 bump 208. This barrier cap 300 may provide improved protection from voids and intermetallic compounds by providing an improved and more encompassing barrier to the copper metal.

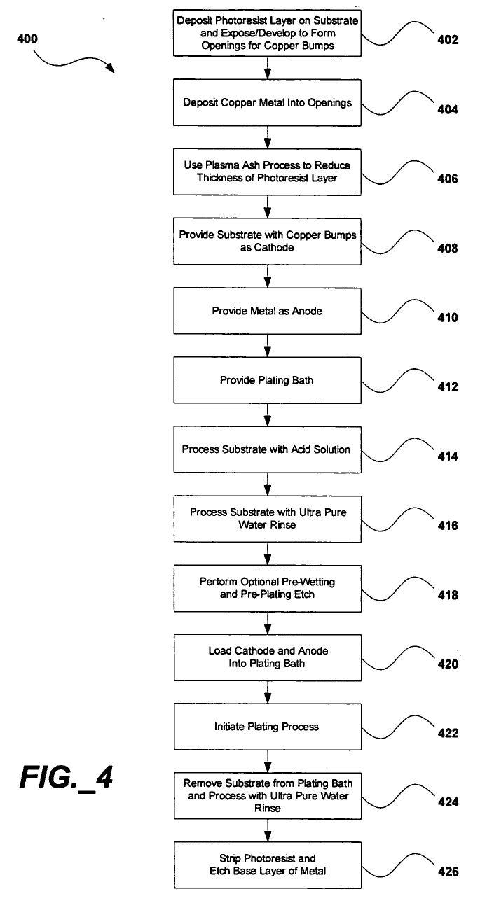

FIG. 4 is a plating process 400 used to form a barrier cap in accordance with an implementation of the invention. In some implementations, an electroplating process may be used to form the barrier caps. In other implementations of the invention, an electroless plating process may be used to form the barrier caps. Both processes will be described here with reference to FIG. 4.

The copper bumps are formed on a substrate, such as a semiconductor wafer, using a conventional C4 plating process. For instance, in one implementation a photoresist layer may be deposited on the substrate surface and then exposed and developed to form openings for the bumps (402). Copper metal may then be deposited into the openings to form the copper bumps (404). Deposition methods that include, but are not limited to, electroplating and electroless plating may be used to form the copper bumps.

Next, the photoresist material is partially removed to reduce its thickness (406). In one implementation, a plasma ash process is used to partially etch away the top surface of the photoresist material. This allows the barrier cap to encapsulate the interface between the barrier cap and the C4 bump. In alternate implementations, this process step may be omitted.

The substrate with the copper bumps and the photoresist material is then provided as a cathode for the plating process 400 used to form the barrier cap (408). In addition, an anode for the plating process 400 is provided (410). The anode may be a piece of metal that matches the metal chosen for the barrier cap. For instance, in implementations where the barrier cap is formed using nickel metal or cobalt metal, the anode may be a piece of nickel metal or cobalt metal. In other implementations, metals other than nickel or cobalt may be used.

A plating bath is also provided for the plating process (412). In implementations using an electroplating process, the plating bath may consist of an acidic bath that contains a salt or mixed salts of the metal or metal alloy chosen for the barrier cap, for instance, nickel chloride, cobalt chloride, nickel sulfate, cobalt sulfate, nickel acetate, nickel fluoborate, nickel sulfamate, nickel formate, cobalt sulfamate, cobalt ammonium sulfate, or cobalt acetate. The electroplating bath may further contain additives that include, but are not limited to, pH buffers, surfactants, wetting agents, and levelers, and other electroplating additives that are well known in the art. In implementations using an electroless plating process, the plating bath may consist of a weak acidic bath that contains a hypophosphite reducer, such as sodium hypophosphite or ammonium hypophosphite, a salt of the metal chosen for the barrier cap, for instance, nickel chloride or cobalt chloride, and one or more complexing agents. The electroless plating bath may further contain additives that include, but are not limited to, pH buffers, surfactants, wetting agents, stabilizers, and levelers, and other electroless plating additives that are well known in the art. In implementations of the invention, the plating bath may be agitated and may be maintained at a temperature between 45° C. and 95° C.

The substrate with the copper bumps and the photoresist material may be treated with an acid solution to remove an oxide layer that may have formed on its surface (414). The substrate may then be rinsed with ultra pure water to remove and residual acid solution (416).

In some implementations of the invention, an optional pre-wetting and pre-plating etch may be performed prior to the plating process being carried out (418). The pre-wetting step allows better contact between the plating solution and the cathode while the pre-plating etch allows for cleaning of the cathode surface.

Next, the substrate with the copper bumps and the photoresist material (i.e., the cathode) and the piece of nickel metal or cobalt metal (i.e., the anode) are loaded into the plating bath (420). The plating process is then initiated to deposit nickel or cobalt metal onto the copper bumps of the substrate (422). In implementations of the invention utilizing an electroplating process, the cathode and the anode are connected to an external direct current (DC) power supply. A DC constant or pulse current output is then applied to the plating bath to bring about the deposition of nickel or cobalt metal onto the copper bumps. In implementations of the invention utilizing an electroless plating process, a chemical reduction/oxidation process occurs with the hypophosphite reducer in the plating bath to bring about the deposition of nickel or cobalt metal onto the copper bumps.

After the plating process, the substrate may be removed from the plating bath and processed with an ultra pure water rinse to remove the residual plating bath solution (424). The substrate may also be dried to remove the water rinse. The remaining portions of the conventional C4 plating process may then be carried out, such as stripping of the photoresist and etching of the base layer of metal in necessary (426).

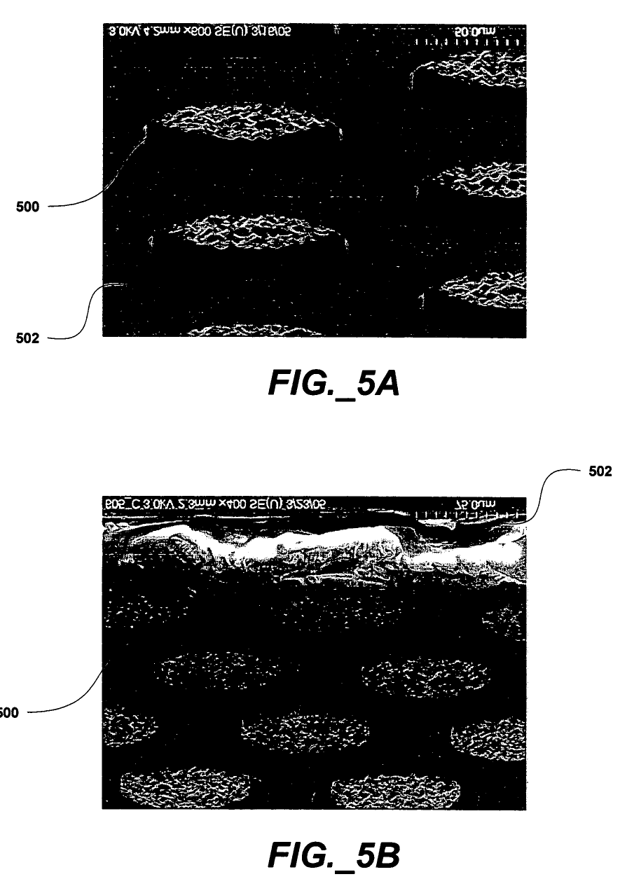

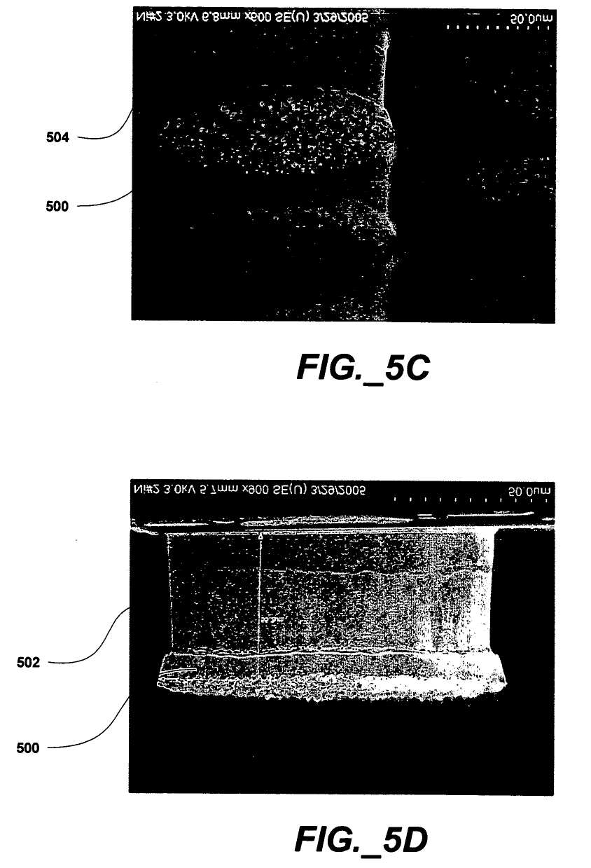

FIGS. 5A to 5D are SEM photographs of the copper bumps during portions of the plating process. FIG. 5A is an SEM photograph of the copper bumps 500 surrounded by the photoresist layer 502. FIG. 5B is an SEM photograph of the copper bumps 500 and the photoresist layer 502 after a plasma etching process has been applied to reduce the thickness of the photoresist layer 502.

FIG. 5C is an SEM photograph of the copper bumps 500 after barrier caps 504 have been plated onto them and after the photoresist layer 502 has been removed. Finally, FIG. 5D is a side view of one copper bump 500 showing the barrier cap 504 that has been plated onto its top surface.

Accordingly, systems and methods of reducing or preventing the electromigration of copper metal into tin metal or tin alloys at the copper-tin interface in C4 connections has been disclosed. Reducing or preventing the electromigration of copper tends to reduce or prevent the formation of voids at the copper-tin interface and prevents intermetallic compounds from being generated, which in turn increases the maximum current that is possible within the C4 connection and increases the reliability of the connection. The systems and methods described above are fairly easy to implement into a high volume manufacturing environment and is easily formed through conventional electroplating or electroless plating technologies.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a C4 bump formed from copper metal; and
a barrier cap formed on a surface of the C4 bump to prevent electromigration of the copper metal.

2. The apparatus of claim 1, wherein the barrier cap comprises nickel metal.

3. The apparatus of claim 1, wherein the barrier cap comprises cobalt metal.

4. The apparatus of claim 1, wherein the barrier cap is formed on only a top surface of the C4 bump.

5. The apparatus of claim 1, wherein the barrier cap encapsulates the C4 bump.

6. A apparatus comprising:
an integrated circuit;
a plurality of C4 bumps on a surface of the integrated circuit, wherein the C4 bumps are formed from copper metal;
a plurality of barrier caps formed on surfaces of the C4 bumps to prevent electromigration of the copper metal;
a carrier substrate; and
a plurality of solder bumps on a surface of the carrier substrate, wherein the solder bumps are formed using tin metal and are coupled to the C4 bumps through the barrier caps.

7. The apparatus of claim 6, wherein the barrier caps comprise nickel metal.

8. The apparatus of claim 6, wherein the barrier caps comprise cobalt metal.

9. The apparatus of claim 6, wherein each barrier cap is formed on only a top surface of each C4 bump.

10. The apparatus of claim 6, wherein each barrier cap encapsulates each C4 bump.

11. The apparatus of claim 6, wherein the carrier substrate comprises a motherboard.

12. The apparatus of claim 6, wherein the tin metal comprises a tin metal alloy.

13. The apparatus of claim 12, wherein the tin metal alloy comprises tin-silver or tin-lead.

14. The apparatus of claim 6, wherein the solder bumps are coupled to the C4 bumps through a reflow process.

15. The apparatus of claim 6, wherein the barrier caps prevent copper metal from electromigrating into the solder bumps.

16. A method comprising:
providing an integrated circuit substrate;
depositing a photoresist layer on a top surface of the integrated circuit substrate;
exposing and developing the photoresist layer to form an opening;
depositing copper metal into the opening to form a C4 bump;
plating a metal barrier layer onto a surface of the C4 bump; and
stripping the photoresist layer.

17. The method of claim 16, further comprising reducing the thickness of the photoresist layer using a plasma ash process.

18. The method of claim 16, wherein the plating of a metal barrier layer on a surface of the C4 bump comprises depositing a metal onto the surface of the C4 bump using an electroplating process.

19. The method of claim 16, wherein the plating of a metal barrier layer on a surface of the C4 bumps comprises depositing a metal onto the surface of the C4 bump using an electroless plating process.

20. The method of claim 16, wherein the metal barrier layer comprises a nickel metal barrier layer.

21. The method of claim 16, wherein the metal barrier layer comprises a cobalt metal barrier layer.

22. The method of claim 16, further comprising processing the C4 bump with an acid solution to remove an oxide layer prior to the plating of the metal barrier layer.

23. The method of claim 16, further comprising performing a pre-wetting process and a pre-plating etch prior to the plating of the metal barrier layer.

24. The method of claim 16, wherein the plated metal barrier layer is formed on a top surface of the C4 bump.

25. The method of claim 16, wherein the plated metal barrier layer encapsulates the C4 bump.

26. The method of claim 18, wherein a plating bath for the electroplating process comprises:
an acidic bath; and
at least one metal salt.

27. The method of claim 26, wherein the metal salt comprises one or more of nickel chloride, cobalt chloride, nickel sulfate, cobalt sulfate, nickel acetate, nickel fluoborate, nickel sulfamate, nickel formate, cobalt sulfamate, cobalt ammonium sulfate, and cobalt acetate.

28. The method of claim 26, wherein the plating bath further comprises a pH buffer, a surfactant, a wetting agent, a stabilizer, and a leveler.

29. The method of claim 19, wherein a plating bath for the electroless plating process comprises:
a weak acidic bath;
a hypophosphite reducer;
at least one metal salt; and
at least one complexing agent.

30. The method of claim 29, wherein the metal salt comprises nickel chloride or cobalt chloride.

31. The method of claim 29, wherein the plating bath further comprises a pH buffers, a surfactant, a wetting agent, and a leveler.
